(19) United States
(12) Patent Application Publication
(10) Pub. No.: US 2007/0284612 A1
(43) Pub. Date: Dec. 13, 2007

(54) SEMICONDUCTOR DEVICES WITH ONE-SIDED BURIED STRAPS

(75) Inventors: Kangguo Cheng, Beacon, NY (US); Ramachandra Divakaruni, Ossining, NY (US); Carl John Radens, LaGrangeville, NY (US)

Correspondence Address: SCHMEISER, OLSEN & WATTS, 22 CENTURY HILL DRIVE, SUITE 302, LATHAM, NY, 12110, US

(73) Assignee: INTERNATIONAL BUSINESS MACHINES CORPORATION, Armonk, NY (US)

(21) Appl. No.: 11/423,280

(22) Filed: Jun. 9, 2006

(51) Int. Cl. H01L 31/00

(52) U.S. Cl. 257/192

(57) ABSTRACT

Structures and methods for forming the same. A semiconductor fabrication method comprises a step of providing a semiconductor structure. The semiconductor structure includes a semiconductor substrate and a capacitor electrode on the semiconductor substrate. The capacitor electrode comprises dopants, and is electrically insulated from the semiconductor substrate by a capacitor dielectric layer. The semiconductor structure further includes a semiconductor layer on the semiconductor substrate. The semiconductor layer comprises a trench which partially but not completely overlaps the capacitor electrode. The method further comprises the step of causing some of the dopants of the capacitor electrode to diffuse into the semiconductor layer, resulting in a doped source/drain region. The doped source/drain region overlaps the capacitor electrode and abuts a sidewall of the trench.

### BACKGROUND OF THE INVENTION

1. Technical Field

The present invention relates to semiconductor devices, and more specifically, to semiconductor devices with one-sided buried straps.

2. Related Art

In a conventional fabrication process of a DRAM cell, the transistor of the DRAM cell can be formed around a trench and electrically coupled to the capacitor through a buried strap region. As the sizes of the devices on the substrate become smaller and smaller, there is a need to form the buried strap region on only one side of the trench. As a result, there is a need for a simpler method for forming the transistor with the one-sided buried strap.

### SUMMARY OF THE INVENTION

The present invention provides a semiconductor structure, comprising (a) a semiconductor substrate; (b) a capacitor electrode on the semiconductor substrate, wherein capacitor electrode comprises dopants, and wherein the capacitor electrode is electrically insulated from the semiconductor substrate by a capacitor dielectric layer; (c) a first doped source/drain region on the capacitor electrode, wherein the doped source/drain region is electrically coupled to the capacitor electrode; and (d) a gate electrode on the capacitor electrode, wherein the gate electrode partially but not completely overlaps the capacitor electrode.

The present invention provides a semiconductor structure fabrication method, comprising providing a semiconductor structure which includes: (a) a semiconductor substrate, (b) a capacitor electrode on the semiconductor substrate, wherein the capacitor electrode is electrically insulated from the semiconductor substrate by a capacitor dielectric layer, and wherein the capacitor electrode comprises dopants, and (c) a semiconductor layer on the semiconductor substrate, wherein the semiconductor layer comprises a trench, and wherein the trench partially but not completely overlaps the capacitor electrode; and causing some of the dopants of the capacitor electrode to diffuse into the semiconductor layer, resulting in a first doped source/drain region, wherein the first doped source/drain region overlaps the capacitor electrode, and wherein the first doped source/drain region abuts a sidewall of the trench.

The present invention provides a simpler method for forming a semiconductor device with the one-sided buried strap.

### BRIEF DESCRIPTION OF THE DRAWINGS

FIGS. 1A-1M illustrate a first fabrication method for forming a first semiconductor structure, in accordance with embodiments of the present invention.

FIGS. 2A-2J illustrate a second fabrication method for forming a second semiconductor structure, in accordance with embodiments of the present invention.

### DETAILED DESCRIPTION OF THE INVENTION

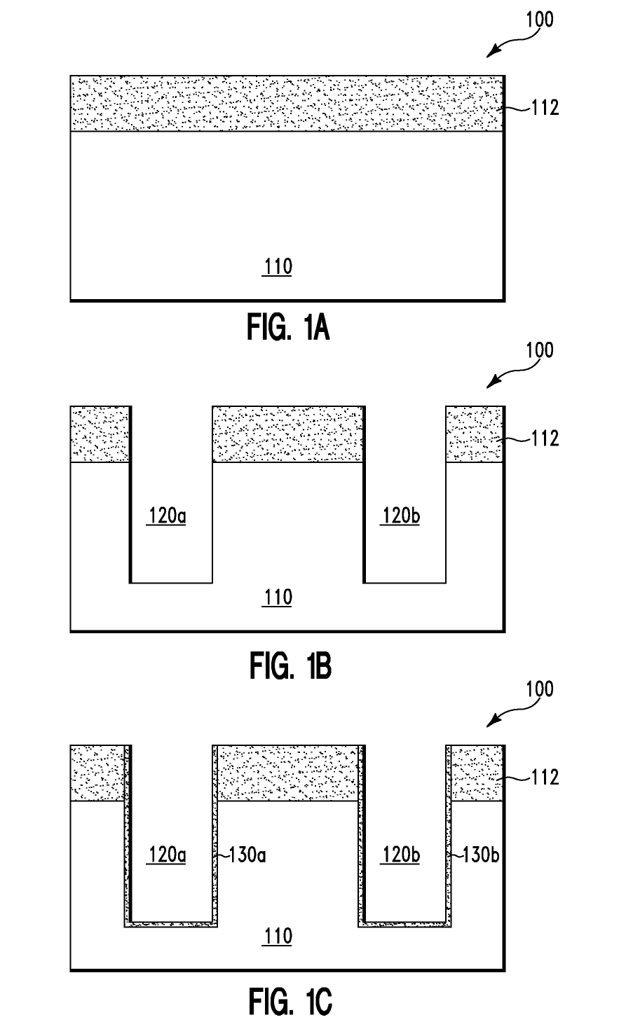

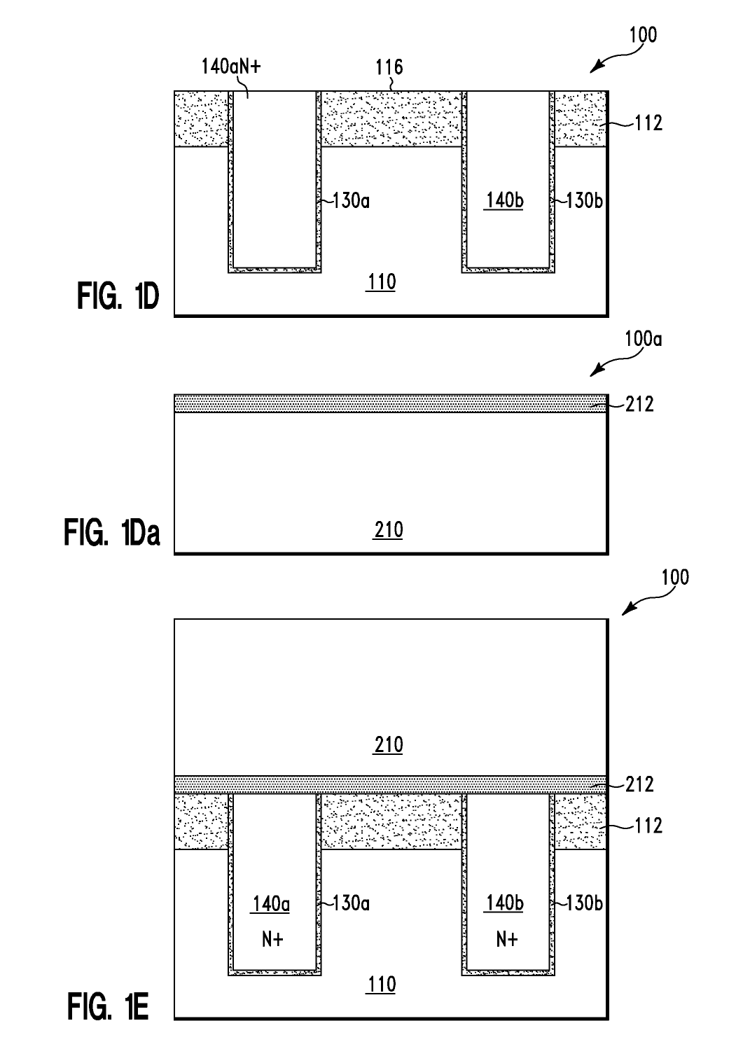

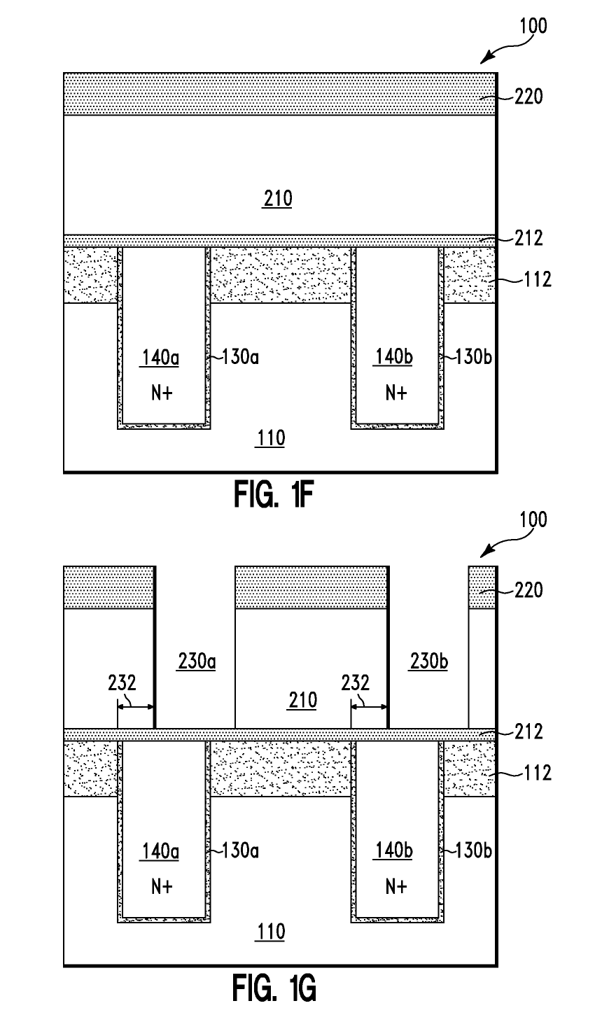

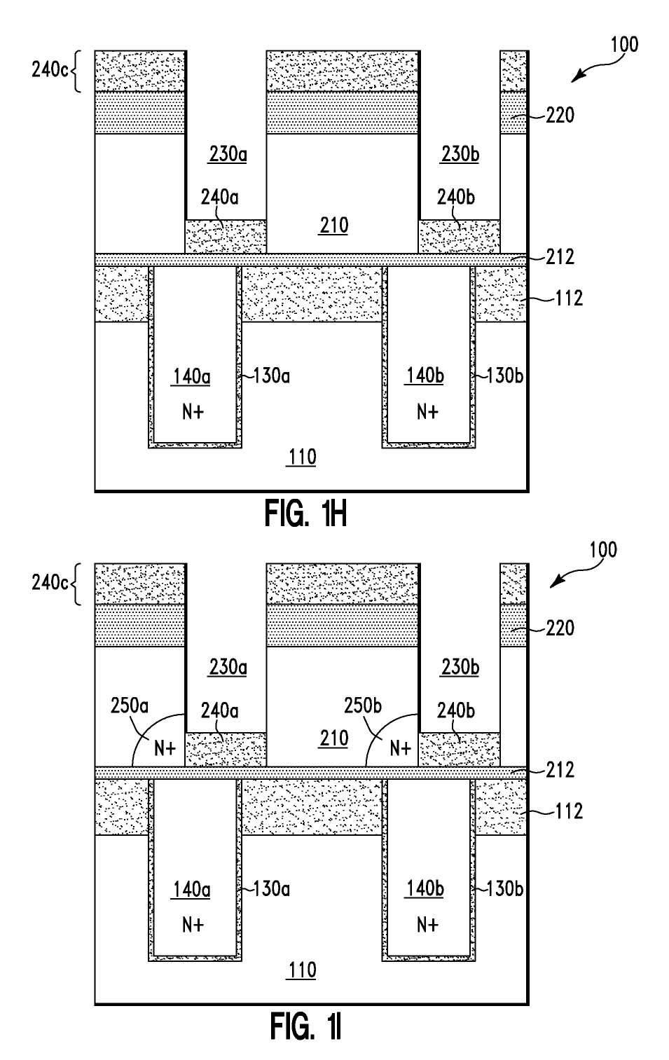

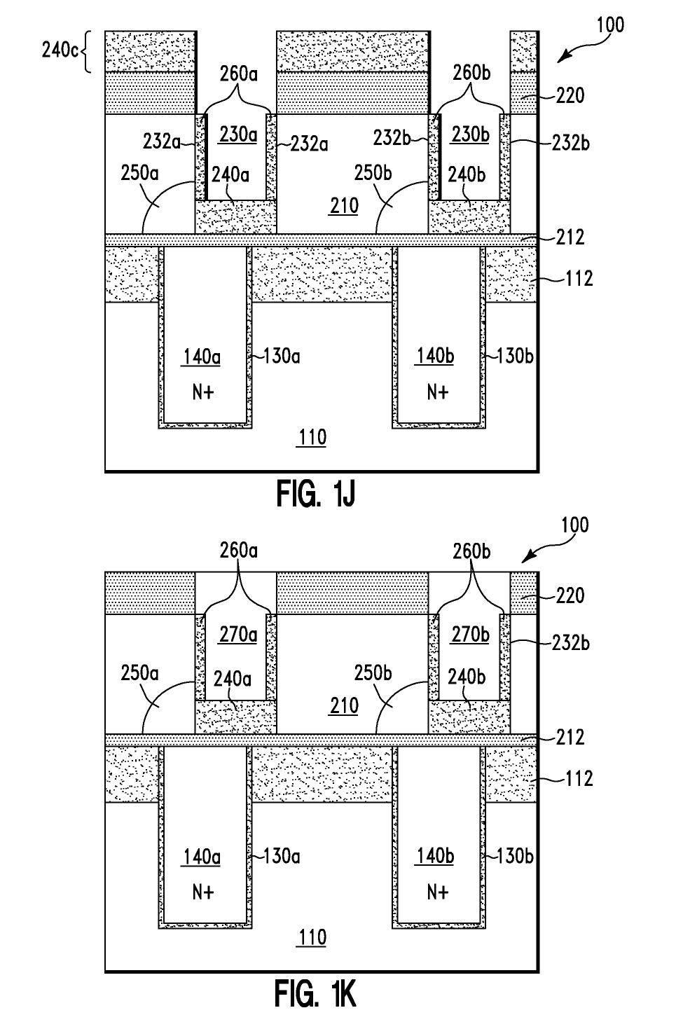

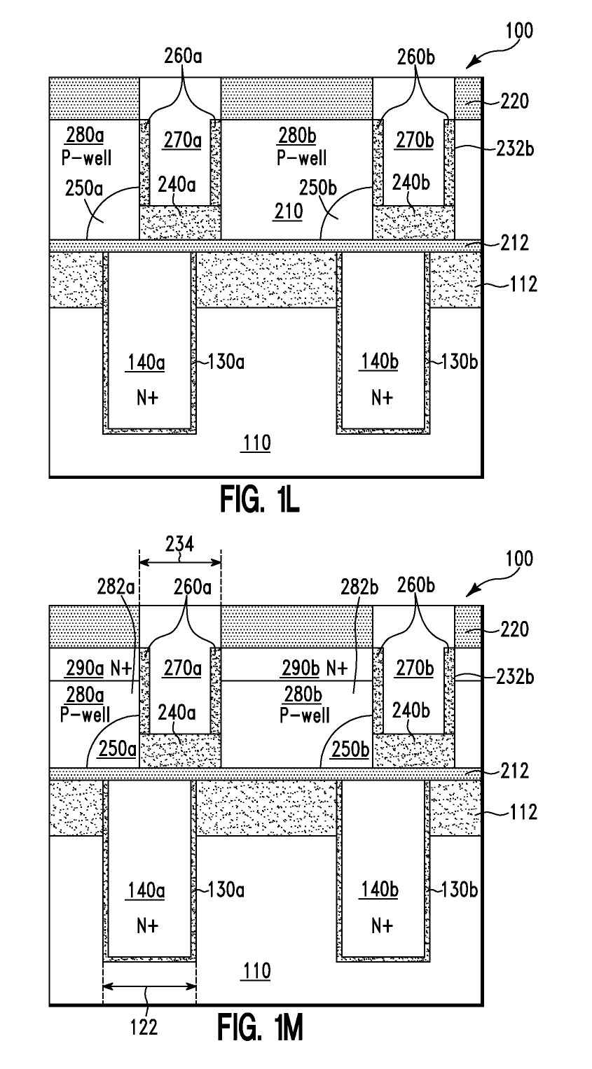

FIGS. 1A-1M illustrate a fabrication method for forming a semiconductor structure 100, in accordance with embodiments of the present invention. More specifically, with reference to FIG. 1A, in one embodiment, the fabrication of the semiconductor structure 100 starts out with a semiconductor substrate 110. Illustratively, the semiconductor substrate 110 comprises a semiconductor material such as silicon (Si), germanium (Ge), silicon germanium (SiGe), silicon carbide (SiC), and those materials consisting essentially of one or more compound semiconductors such as gallium arsenic (GaAs), gallium nitride (GaN), and indium phosphoride (InP), etc.

Next, in one embodiment, an insulating layer 112 is formed on top of the semiconductor substrate 110. In one embodiment, the insulating layer 112 comprise silicon oxide formed by thermal oxidation or by CVD (Chemical Vapor Deposition).

Next, with reference to FIG. 1B, in one embodiment, trenches 120a and 120b are formed in the structure 100 of the FIG. 1A. In one embodiment, the trenches 120a and 120b are formed using a conventional patterning and etching processes.

Next, with reference to FIG. 1C, in one embodiment, node dielectric layers 130a and 130b are formed on side walls and bottom walls of the trenches 120a and 120b, respectively. The dielectric layers 130a and 130b may comprise any dielectric material, including but not limited to, silicon nitride, silicon oxide, silicon oxynitride, high-k (high dielectric) material, or any suitable combination of these materials. The dielectric layers 130a and 130b can be formed by any suitable process, including but not limited to thermal oxidation, thermal nitridation, CVD, and/or ALD (atomic layer deposition).

Next, in one embodiment, the trenches 120a and 120b are filled with a conducting material, resulting in capacitor electrodes 140a and 140b in FIG. 1D. Illustratively, the capacitor electrodes 140a and 140b (FIG. 1D) are formed by depositing an N-type doped polysilicon on top of the entire structure 100 in FIG. 1C (including in the trenches 120a and 120b) and then planarizing by a CMP (chemical mechanical polishing) step to remove the excessive polysilicon outside the trenches 120a and 120b.

FIG. 1Da illustrates a semiconductor structure 100a, in accordance with embodiments of the present invention. More specifically, with reference to FIG. 1Da, in one embodiment, the fabrication of the semiconductor structure 100a starts out with a semiconductor substrate 210. The semiconductor substrate 210 may comprise a material as same as or different from the substrate 110. Furthermore, the semiconductor substrate 210 may have a crystallographic orientation as same as or different from the crystallographic orientation of the substrate 110.

Next, in one embodiment, optionally, a dielectric layer 212 is formed on top of the semiconductor substrate 210 to facilitate the subsequent bonding process. The dielectric layer 212, when present, has a thickness thin enough to allow dopants to diffuse through it and allow carriers (electrons and holes) to tunneling through it. More specifically, the dielectric layer 212 may comprises a thin silicon nitride, silicon carbide, or silicon oxide formed by thermal oxidation, thermal nitridation, chemical oxidation, chemical nitridation, CVD, or ALD process. Preferably, the dielectric layer 212 has a thickness ranging from about 5 to 25 angstroms, and more preferably from 5 to 15 angstroms, and most preferably from 7 to 10 angstroms.

Next, in one embodiment, the structure 100a in FIG. 1Da is turned upside down and then bonded to a top surface 116 of the structure 100 in FIG. 1D, resulting in the structure 100 of FIG. 1E. Next, in one embodiment, the substrate 210 can be thinned to the desired thickness by cleaving, grinding, polishing, or combination of some or all of these processes.

Next, with reference to FIG. 1F, in one embodiment, a pad layer 220 is formed on top of the structure 100 of FIG. 1E. In one embodiment, the pad layer 220 comprises silicon nitride on top of the region 210. In one embodiment, the pad layer 220 is formed by CVD.

Next, with reference to FIG. 1G, in one embodiment, offset trenches 230a and 230b are formed in the pad layer 220 and the semiconductor substrate 210 of the FIG. 1F, in which the offset trenches 230a and 230b can be aligned to the trenches 120a and 120b, respectively, with an offset 232 (as shown in FIG. 1G). In one embodiment, the offset trenches 230a and 230b are formed using conventional patterning and etching processes. In one embodiment, the step of etching to form the offset trenches 230a and 230b essentially stops at the dielectric layer 212.

Next, with reference to FIG. 1H, in one embodiment, insulating layers 240a and 240b are formed in the offset trenches 230a and 230b, respectively. In one embodiment, the insulating layers 240a and 240b comprise silicon oxide formed by HDP (high density plasma) deposition followed by a timed etchback to remove the deposited material from the trench sidewall, leaving TTO (trench top oxide) at the bottom of the offset trenches 230a and 230b. The insulating layer material 240c may also be formed on top of the pad layer 220.

Next, in one embodiment, the structure 100 in FIG. 1H is heated up at a temperature to form one-sided buried straps 250a and 250b (also called doped source/drain regions 250a and 250b) as shown in FIG. 1I. During the heating step, the dopants in the doped polysilicon of the capacitor electrodes 140a and 140b diffuse into the semiconductor substrate 210, resulting in the one-sided buried straps 250a and 250b in FIG. 1I. Preferably, the annealing step is performed at a temperature ranging from 800 to 1150 Celsius degrees for duration from 5 seconds to 120 minutes. Alternatively, the buried straps 250a and 250b can be formed by driving the dopants in the doped polysilicon of the capacitor electrodes 140a and 140b into the substrate 210 in the later thermal processes.

As described above, the dielectric layer 212, if present, is thin enough to allow dopants to diffuse through it and allow carriers (electrons and holes) to tunnel through it to ensure a good electrical connection between the buried straps (250a and 250b) and the capacitor electrodes 140a and 140b, respectively.

Next, with reference to FIG. 1J, in one embodiment, gate dielectric regions 260a and 260b are formed on side walls of the offset trenches 230a and 230b, respectively. In one embodiment, the gate dielectric regions 260a and 260b can be formed by thermally oxidizing side wall surfaces 232a and 232b of the offset trenches 230a and 230b, respectively.

Next, in one embodiment, the offset trenches 230a and 230b are filled with a conducting material, resulting in gate electrodes 270a and 270b in FIG. 1K. Illustratively, the gate electrodes 270a and 270b are formed by depositing polysilicon on top of the entire structure 100 in FIG. 1J (including in the offset trenches 230a and 230b) and then polishing by a CMP step to remove the excessive polysilicon outside the offset trenches 230a and 230b. The TTO material 240c on top of the pad layer 220 can be removed by conventional etching process at this step.

Next, with reference to FIG. 1L, in one embodiment, well regions 280a and 280b are formed in the semiconductor substrate 210. In one embodiment, the well regions 280a and 280b are formed by ion implantation of P-type dopants such as boron or indium.

Next, with reference to FIG. 1M, in one embodiment, source/drain regions 290a and 290b are formed in the P-well regions 280a and 280b, respectively. In one embodiment, the source/drain regions 290a and 290b (also called second doped source/drain regions 290a and 290b) are formed by ion implantation of N-type dopants such as phosphorous or arsenic.

It should be noted that there are first and second DRAM (Dynamic Random Access Memory) cells in FIG. 1M. More specifically, the first DRAM cell comprises a first capacitor 140a+130a+110 and a first vertical transistor 250a+260a+270a+282a+290a, which are electrically coupled together. The first capacitor 140a+130a+110 comprises a capacitor dielectric layer 130a, a first capacitor electrode 140a, and a second capacitor electrode 110. The first vertical transistor 250a+260a+270a+282a+290a comprises a first source/drain region 250a, a second source/drain region 290a, a channel region 282a (a portion of the P-well region 280a as shown in FIG. 1M), the gate dielectric region 260a, and the gate electrode 270a. The second DRAM cell comprises a second capacitor 140b+130b+110 and a second vertical transistor 250b+260b+270b+282b+290b, which are electrically coupled together. The second capacitor 140b+130b+110 comprises a capacitor dielectric layer 130b, a first capacitor electrode 140b, and a second capacitor electrode 110. The second vertical transistor 250b+260b+270b+282b+290b comprises a first source/drain region 250b, a second source/drain region 290b, a channel region 282b (a portion of the P-well region 280b as shown in FIG. 1M), the gate dielectric region 260b, and the gate electrode 270b.

In one embodiment, with reference to FIG. 1M, a width 234 of the cross-section of the gate electrode 270a is essentially the same as a width 122 of the cross-section of the capacitor electrode 140a. In an alternative embodiment, to increase the capacitance of the first capacitor 140a+130a+110, the trench 120a (in FIG. 1B) can be widened, therefore, the width 122 of capacitor electrode 140a is greater than the width 234 of the cross-section of the gate electrode 270a.

It should be noted that if the buried strap 250a was formed on both side (left and right) of the TTO layer 240a, there would be a risk of the buried strap 250a shorting to the buried strap 250b. As a result, by forming the buried strap 250a only on one side of the TTO layer 240a, the two DRAM cells can be formed closer together, therefore, increasing the density of the final product.

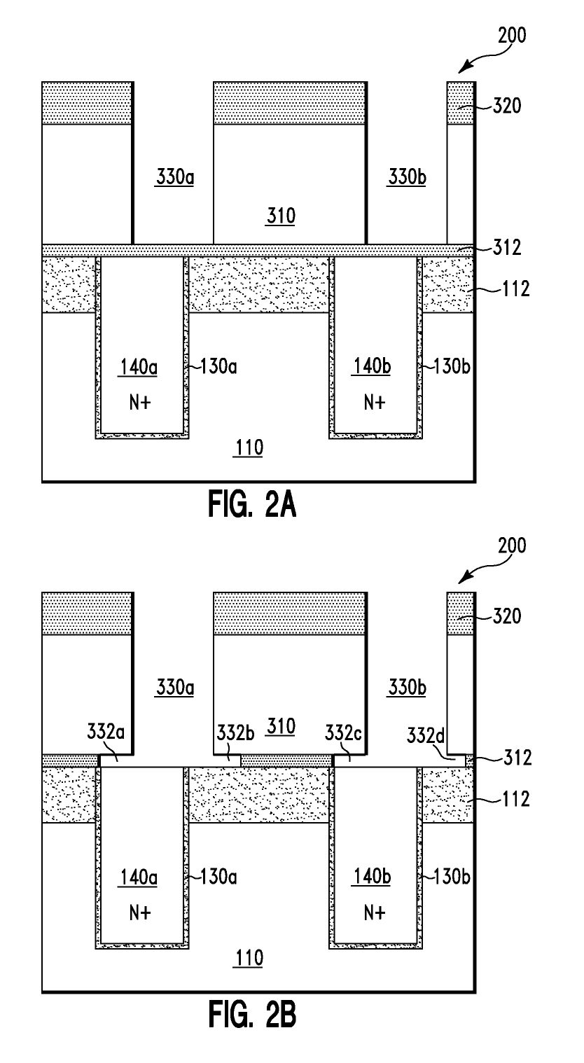

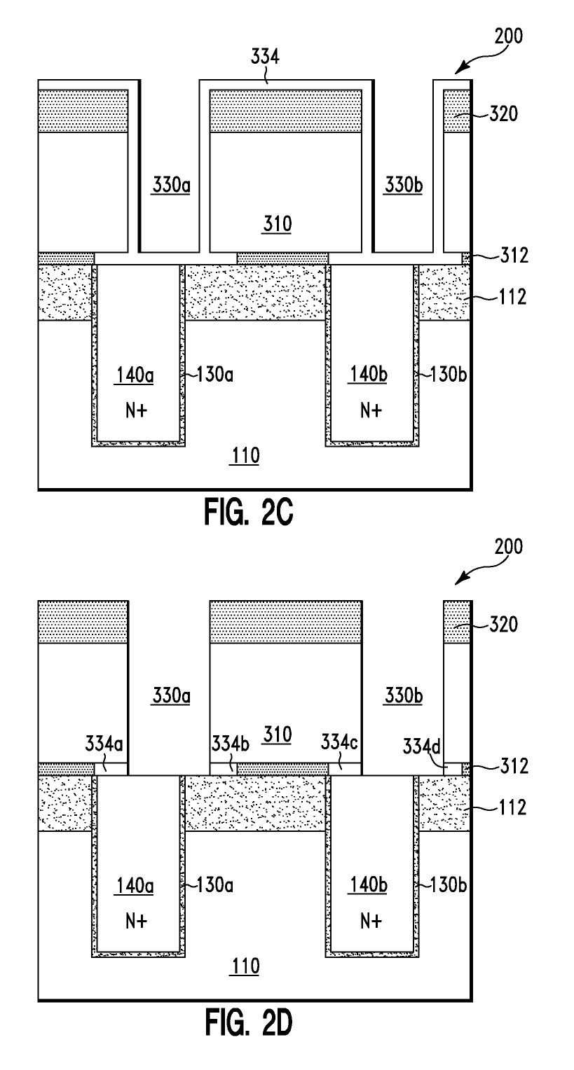

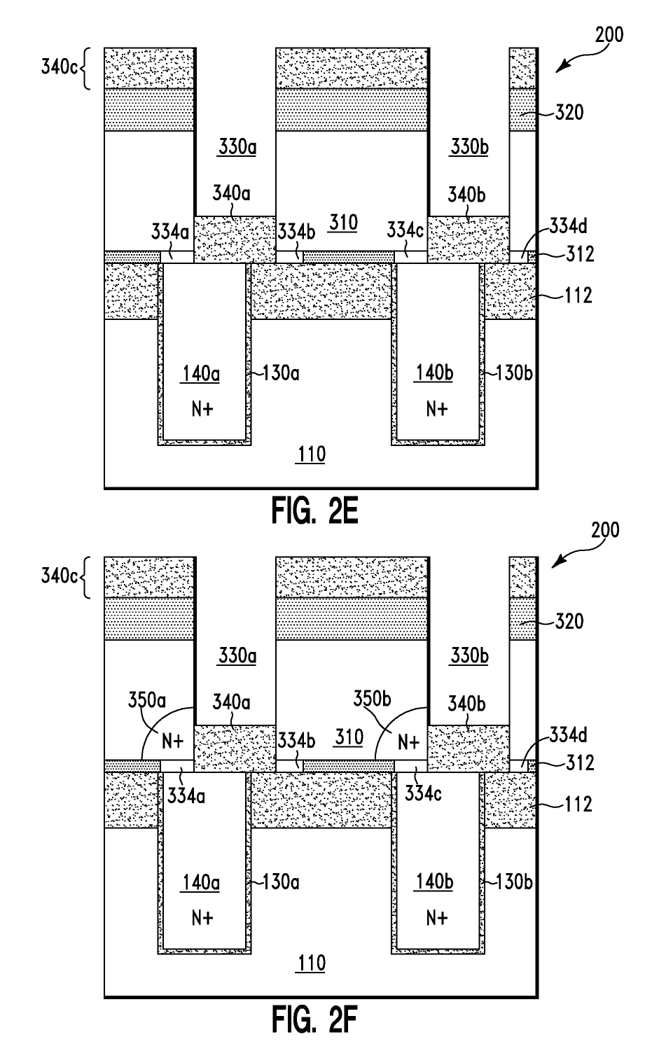

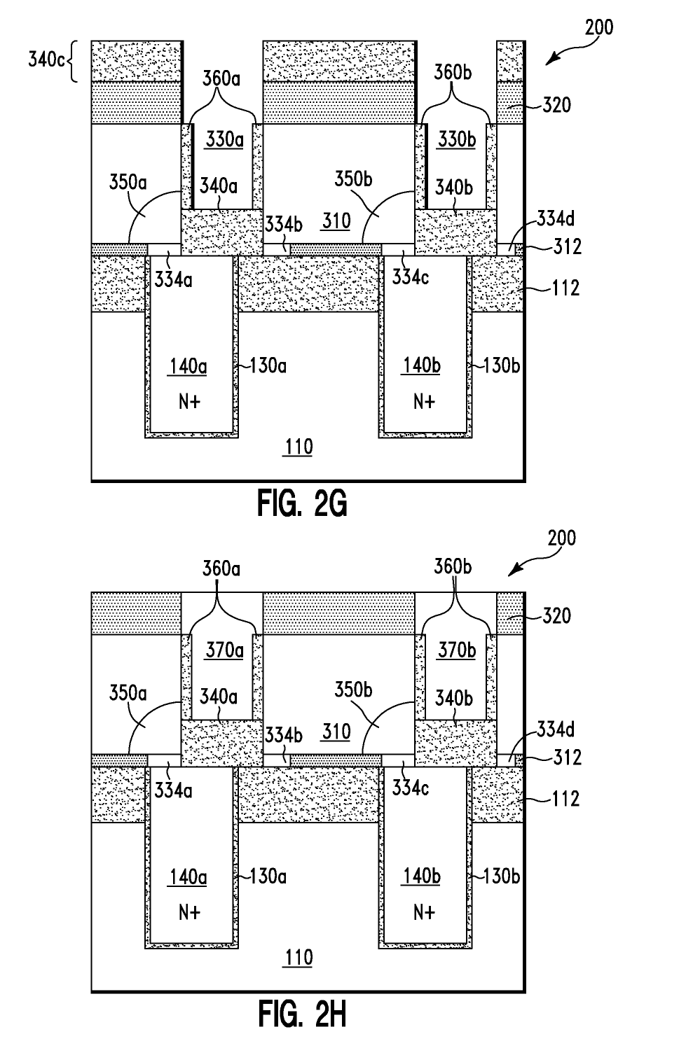

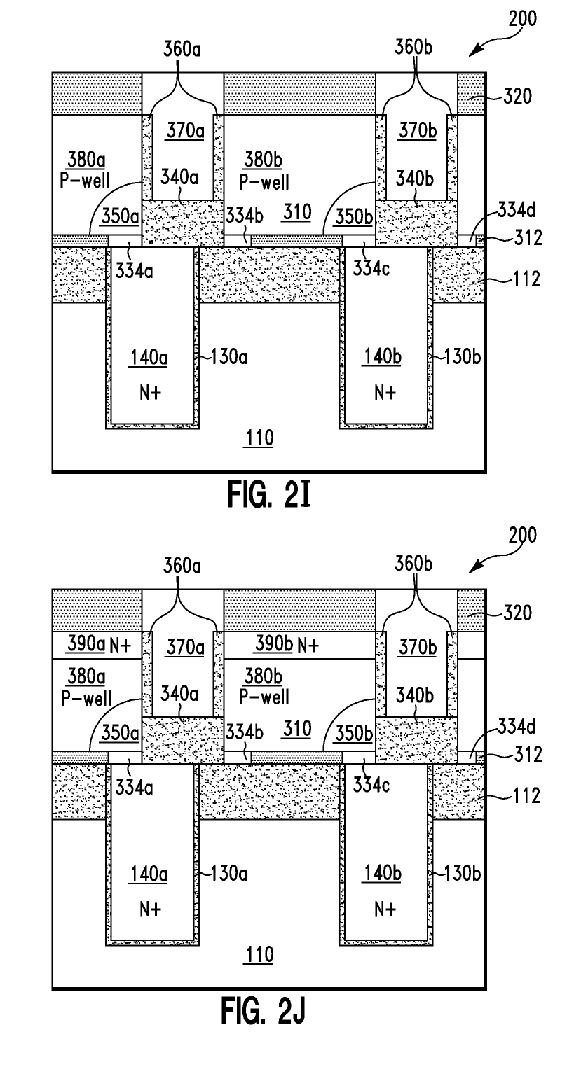

FIGS. 2A-2J illustrate a second fabrication method for forming a second semiconductor structure 200, in accordance with embodiments of the present invention. More specifically, in one embodiment, the second fabrication method starts out with the structure 200 in FIG. 2A. In one embodiment, the structure 200 in FIG. 2A is similar to the structure 100 in FIG. 1G. In another embodiment, dielectric layer 312 in FIG. 2A is substantially thicker than the dielectric layer 212 in FIG. 1G. In one embodiment, the dielectric layer 312 in FIG. 2A has a thickness ranging from 50 to 1000 angstroms. Illustratively, the formation of the structure 200 in FIG. 2A is similar to the formation of the structure 100 in FIG. 1G. It should be noted that similar regions of the bottom part of the structure 200 in FIG. 2A, and the bottom part of the structure 100 in FIG. 1G (which are similar to the structure 100 in FIG. 1D) have the same reference numerals. It also should be noted that the similar remaining regions of the structure 200 in FIG. 2A and the structure 100 in FIG. 1G have the same reference numerals, except for the first digit. For instance, offset trenches 330a and 330b (FIG. 2A) and the offset trenches 230a and 230b (FIG. 1G) are respectively similar.

Next, in one embodiment, exposed portions of the thin dielectric layer 312, when present, are removed by an etching step which is essentially selective to the semiconductor substrate 310, the polysilicon of the capacitor electrodes 140a and 140b, and the BOX layer 112, resulting in four undercut spaces 332a, 332b, 332c, and 332d as shown in FIG. 2B. In one embodiment, the removal of the exposed portions of the thin dielectric layer 312 can be achieved by an isotropic etch such as a wet etch or a plasma etch.

Next, with reference to FIG. 2C, in one embodiment, a conducting layer 334 is formed on the entire structure 200 (including in the trenches 330a and 330b, and the four undercut spaces 332a, 332b, 332c, and 332d). In one embodiment, the conducting layer 334 comprises polysilicon is formed by conventional CVD method. In one embodiment, a thin barrier layer (not shown) is formed on exposed silicon surfaces of the structure 200 in FIG. 2B prior to the deposition of the conducting layer 334 to prevent defect formation in the subsequent processes. The thin barrier layer, when present, has a thickness thin enough to allow dopants to diffuse through it and allow carriers (electrons and holes) to tunnel through it. More specifically, the thin barrier layer may comprises a thin silicon nitride, silicon carbide, or silicon oxide formed by thermal oxidation, thermal nitridation, chemical oxidation, chemical nitridation, CVD, or ALD process. Preferably, the thin barrier layer has a thickness ranging from about 5 to 25 angstroms, and more preferably from 5 to 15 angstroms, and most preferably from 7 to 10 angstroms.

Next, in one embodiment, exposed portions of the conducting layer 334 are removed, resulting in four buried straps 334a, 334b, 334c, and 334d, as shown in FIG. 2D. In one embodiment, the formation of the FIG. 2D is achieved by a timed isotropic etching step.

Next, with reference to FIG. 2E, in one embodiment, TTO (Trench Top Oxide) layers 340a, 340b, and 340c are formed in the offset trenches 330a, 330b, and the pad layer 320, respectively. More specifically, the formation of the TTO layers 340a, 340b, 340c are similar to the formation of the TTO layers 240a, 240b, 240c in FIG. 1H.

Next, with reference to FIG. 2F, in one embodiment, one-sided buried straps 350a and 350b are formed in the semiconductor substrate 310. More specifically, the formation of the one-sided buried straps 350a and 350b are similar to the formation of the one-sided buried straps 250a and 250b in FIG. 1I. Regions 334b and 334d are isolated from the capacitor electrodes 140a and 140b by TTO layers 340a, 340b, and the BOX layer 112. In one embodiment, the structure 200 in FIG. 2E is heated up at a temperature to form one-sided buried straps 350a and 350b (also called doped source/drain regions 350a and 350b) as shown in FIG. 2F. During the heating step, the dopants in the doped polysilicon of the capacitor electrodes 140a and 140b diffuse into the semiconductor substrate 210, resulting in the one-sided buried straps 350a and 350b in FIG. 2F. Preferably, the annealing step is performed at a temperature ranging from 800 to 1150 Celsius degrees for a duration from 5 seconds to 120 minutes. Alternatively, the buried straps 350a and 350b can be formed by driving the dopants in the doped polysilicon of the capacitor electrodes 140a and 140b into the substrate 310 in the later thermal processes.

Next, with reference to FIG. 2G, in one embodiment, gate dielectric regions 360a and 360b are formed. More specifically, the formation of the gate dielectric regions 360a and 360b are similar to the formation of the gate dielectric regions 260a and 260b in FIG. 1J.

Next, with reference to FIG. 2H, in one embodiment, gate electrodes 370a and 370b are formed. More specifically, the formation of the gate electrodes 370a and 370b are similar to the formation of the gate electrodes 270a and 270b in FIG. 1K.

Next, with reference to FIG. 2I, in one embodiment, P-well regions 380a and 380b are formed. More specifically, the formation of the P-well regions 380a and 380b are similar to the formation of the P-well regions 280a and 280b in FIG. 1L.

Next, with reference to FIG. 2J, in one embodiment, source/drain regions 390a and 390b are formed. More specifically, the formation of the source/drain regions 390a and 390b are similar to the formation of the source/drain regions 290a and 290b in FIG. 1M.

It should be noted that there are two DRAM cells in FIG. 2J and this two DRAM cells have the features of the two DRAM cells in FIG. 1M.

In the embodiments described above, the first and second transistors of the first and second DRAM cells, respectively, are vertical devices. Alternatively, the first and second transistors can be planar devices.

While particular embodiments of the present invention have been described herein for purposes of illustration, many modifications and changes will become apparent to those skilled in the art. Accordingly, the appended claims are intended to encompass all such modifications and changes as fall within the true spirit and scope of this invention.

1. A semiconductor structure, comprising:
(a) a semiconductor substrate;
(b) a capacitor electrode on the semiconductor substrate,
wherein capacitor electrode comprises dopants, and
wherein the capacitor electrode is electrically insulated from the semiconductor substrate by a capacitor dielectric layer;
(c) a first doped source/drain region on the capacitor electrode, wherein the doped source/drain region is electrically coupled to the capacitor electrode; and
(d) a gate electrode on the capacitor electrode, wherein the gate electrode partially but not completely overlaps the capacitor electrode.

2. The structure of claim 1, wherein the first doped source/drain region and the capacitor electrode comprise dopants of a same doping polarity.

3. The structure of claim 1, further comprising:
a gate dielectric region, wherein the first doped source/drain region and the gate electrode are electrically insulated from each other by the gate dielectric region;
a second doped source/drain region,
wherein the second doped source/drain region and the first doped source/drain region comprise dopants of a same doping polarity, and
wherein the second doped source/drain region and the gate electrode are electrically insulated from each other by the gate dielectric region; and
a channel region,
wherein the channel region and the first doped source/drain region comprise dopants of opposite doping polarities, and
wherein the channel region is disposed between the first doped source/drain region and the second doped source/drain region.

4. The structure of claim 1, wherein the capacitor electrode and the gate electrode are electrically insulated from each other.

5. The structure of claim 4, wherein the capacitor electrode and the gate electrode are electrically insulated from each other by a trench top oxide.

6. The structure of claim 1, wherein the first doped source/drain region and the capacitor electrode is electrically coupled together through a thin film layer.

7. The structure of claim 6, wherein the thin film layer comprises a material which is selected from the group consisting of silicon oxide, silicon nitride, and silicon carbide.

8. The structure of claim 1, wherein the first doped source/drain region and the capacitor electrode is electrically coupled together through a buried strap region.

9. The structure of claim 1, wherein the first doped source/drain region overlaps the capacitor electrode.

10. The structure of claim 1, wherein a width of the capacitor electrode is larger than a width of the gate electrode.

11. A semiconductor structure fabrication method, comprising:
providing a semiconductor structure which includes:
(a) a semiconductor substrate,
(b) a capacitor electrode on the semiconductor substrate,
wherein the capacitor electrode is electrically insulated from the semiconductor substrate by a capacitor dielectric layer, and
wherein the capacitor electrode comprises dopants, and
(c) a semiconductor layer on the semiconductor substrate,
wherein the semiconductor layer comprises a trench, and
wherein the trench partially but not completely overlaps the capacitor electrode; and
causing some of the dopants of the capacitor electrode to diffuse into the semiconductor layer, resulting in a first doped source/drain region,
wherein the first doped source/drain region overlaps the capacitor electrode, and
wherein the first doped source/drain region abuts a sidewall of the trench.

12. The method of claim 11, wherein the capacitor electrode comprises doped polysilicon.

13. The method of claim 11, wherein the first doped source/drain region comprises doped

14. The method of claim 11, further comprising:
forming a gate dielectric region on the sidewall of the trench; then
filling the trench with an electrically conducting material, resulting in a gate electrode, wherein the first doped source/drain region and the gate electrode are electrically insulated from each other by the gate dielectric region; and then
forming a second doped source/drain region in the semiconductor layer,
wherein a channel region is disposed between the first doped source/drain region and the second doped source/drain region,
wherein the first doped source/drain region and the second doped source/drain region comprise dopants of a same doping polarity,
wherein the second doped source/drain region and the gate electrode are electrically insulated from each other by the gate dielectric region, and
wherein the channel region and the first doped source/drain region comprise dopants of opposite doping polarities.

15. The method of claim 14, wherein the capacitor electrode and the gate electrode are electrically insulated from each other.

16. The method of claim 11, where in said providing the semiconductor substrate comprises:
providing a first semiconductor substrate comprising a trench capacitor; and
bonding a second semiconductor substrate with the first semiconductor substrate.

17. The method of claim 16, further comprising forming a dielectric layer on top of the second semiconductor substrate.

18. The method of claim 11, further comprising forming a TTO (trench top oxide) that electrically isolates the gate electrode and the capacitor electrode.

19. The method of claim 11, further comprising, before said causing is performed:
undercutting the semiconductor layer at a bottom of the trench resulting in an undercut space; and then
filling the undercut space with an electrically conductive material resulting a buried strap region,
wherein during said causing is performed, the dopants of the capacitor electrode that diffuse into the semiconductor layer diffuse through the buried strap region.

20. The method of claim 11, wherein the doped source/drain region overlaps the capacitor electrode.
